(19) United States
(12) Patent Application Publication
(10) Pub. No.: US 2026/0280166 A1
(43) Pub. Date: Sep. 17, 2026

(54) PREVENTION OF MODULE MISALIGNMENT USING A SOCKET SYSTEM

(71) Applicant: DELL PRODUCTS L.P., Round Rock, TX (US)

(72) Inventors: Yayun LIU, Austin, TX (US); Michael LO, Round Rock, TX (US)

(73) Assignee: DELL PRODUCTS L.P., Round Rock, TX (US)

(21) Appl. No.: 19/080,823

(22) Filed: Mar. 15, 2025

(51) Int. Cl. H01R 12/72; H01R 12/73; H01R 13/627; H01R 13/64; H05K 7/20

(52) U.S. Cl. CPC H01R 12/721; H01R 12/737; H01R 13/6273; H01R 13/64; H05K 7/20145

(57) ABSTRACT

Presented herein are embodiments comprising one or more mechanical stoppers or flanges, which are moveable relative to insertion and removal of a module into a socket. In one or more embodiments, the stopper/flange may be combined with, or operate in conjunction with, a module latch to form a latch-and-stopper system. Such a system may be added to a socket system or may be integrated as part of a socket system. In one or more embodiments, when a latch is engaged by a module, one or more stoppers/flanges extends and retracts—moving from one position (e.g., open) to another (e.g., closed) or vice versa according to the insertion or removal of the module into or out of the socket.

### BACKGROUND

### A. Technical Field

The present disclosure relates generally to information handling systems. More particularly, the present disclosure relates to sockets for receiving modules.

### B. Background

The subject matter discussed in the background section shall not be assumed to be prior art merely as a result of its mention in this background section. Similarly, a problem mentioned in the background section or associated with the subject matter of the background section should not be assumed to have been previously recognized in the prior art. The subject matter in the background section merely represents different approaches, which in and of themselves may also be inventions.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use, such as financial transaction processing, airline reservations, enterprise data storage, or global communications. In addition, information handling systems may include a variety of hardware and software components that may be configured to process, store, and communicate information and may include one or more computer systems, data storage systems, and networking systems.

A common feature of information handling systems is modular design that allows for the quick addition and/or removal of modular components. One such modular element is computer memory. By having sockets with receptables that include electrical connectors to interface with a memory module, memory modules can be readily inserted or removed. Such a feature if very beneficial as it allows for the rapid and easy addition of memory or changing of memory (e.g., to upgrade to faster memory modules, memory modules with more memory, replacing a bad memory module, etc.).

For example, the physical design of Dell PowerEdge (PE) server motherboards includes a number of parallel sockets that are designed to receive memory modules, such as dual inline memory modules (DIMMs). With the increasing demands for more memory capacity in servers, there has been an increasing number of DIMM sockets on each board. This increase in memory sockets on a board has led to narrow spacing between the sockets. This design increases the risk of a DIMM accidentally being inserted into the empty space between adjacent sockets, rather than being directly inserted into a DIMM slot/receptable. When a DIMM is misaligned and pressed into the gap between sockets, it can damage the components on DIMMs and potentially harm one or more motherboard components.

Accordingly, it is highly desirable to find new systems and methods for supporting a dense number of sockets on a board but that protect against inadvertent misalignment of modules into a socket.

### BRIEF DESCRIPTION OF THE DRAWINGS

References will be made to embodiments of the disclosure, examples of which may be illustrated in the accompanying figures. These figures are intended to be illustrative, not limiting. Although the accompanying disclosure is generally described in the context of these embodiments, it should be understood that it is not intended to limit the scope of the disclosure to these particular embodiments. Items in the figures may not be to scale.

FIG. 1 (“FIG. 1”) depicts a cross-section view of part of a socket system with a gating/stopper/flange mechanism, according to embodiments of the present disclosure.

FIG. 2 depicts an isometric view of part of a socket system with a gating/stopper/flange mechanism, according to embodiments of the present disclosure.

FIG. 3 depicts a partial cross-section view of part of a socket system with a gating/stopper/flange mechanism, according to embodiments of the present disclosure.

FIG. 4 depicts a shaded partial cross-section view of part of a socket system with a gating/stopper/flange mechanism, according to embodiments of the present disclosure.

FIG. 5 depicts an isometric view of part of a socket system with a gating/stopper/flange mechanism in an extended position, according to embodiments of the present disclosure.

FIG. 6 depicts a shaded isometric view of part of a socket system with a gating/stopper/flange mechanism in an extended position, according to embodiments of the present disclosure.

FIG. 7 depicts a shaded isometric view of part of a socket system with a gating/stopper/flange mechanism in a closed or retracted position, according to embodiments of the present disclosure.

FIG. 8 depicts an isometric view of part of a socket system with a gating/stopper/flange mechanism in mid-closed or mid-retracted position, according to embodiments of the present disclosure.

FIG. 9 depicts a shaded isometric view of part of a socket system with a gating/stopper/flange mechanism in mid-closed or mid-retracted position, according to embodiments of the present disclosure.

FIG. 10 depicts a shaded isometric view of part of a socket system with a gating/stopper/flange mechanism in a closed or retracted position, according to embodiments of the present disclosure.

FIG. 11 depicts two partial cross-sectional shaded views of part of a socket system with a gating/stopper/flange mechanism in a closed or retracted position, according to embodiments of the present disclosure.

FIG. 12 depicts two partial shaded isometric views of part of a socket system with a gating/stopper/flange mechanism in an open/extended position 1205 and in a closed/retracted position 1210, according to embodiments of the present disclosure.

FIG. 13 depicts a top view of a set of socket systems with gating/stopper/flange mechanisms, according to embodiments of the present disclosure.

FIG. 14 depicts a methodology for using a socket system, according to embodiments of the present disclosure.

FIG. 15 depicts a simplified block diagram of an information handling system, according to embodiments of the present disclosure.

FIG. 16 depicts an alternative block diagram of an information handling system, according to embodiments of the present disclosure.

### DETAILED DESCRIPTION OF EMBODIMENTS

In the following description, for purposes of explanation, specific details are set forth in order to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, or modules, shown in diagrams are illustrative of exemplary embodiments of the disclosure and are meant to avoid obscuring the disclosure. It shall be understood that throughout this discussion that components may be described as separate functional units, which may comprise sub-units, but those skilled in the art will recognize that various components, or portions thereof, may be divided into separate components or may be integrated together, including, for example, being in a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” “communicatively coupled,” “interfacing,” “interface,” or any of their derivatives shall be understood to include direct connections, indirect connections through one or more intermediary devices, and wireless connections. It shall also be noted that any communication, such as a signal, response, reply, acknowledgement, message, query, etc., may comprise one or more exchanges of information.

Reference in the specification to “one or more embodiments,” “preferred embodiment,” “an embodiment,” “embodiments,” or the like means that a particular feature, structure, characteristic, or function described in connection with the embodiment is included in at least one embodiment of the disclosure and may be in more than one embodiment. Also, the appearances of the above-noted phrases in various places in the specification are not necessarily all referring to the same embodiment or embodiments.

The use of certain terms in various places in the specification is for illustration and should not be construed as limiting. The terms “include,” “including,” “comprise,” “comprising,” and any of their variants shall be understood to be open terms, and any examples or lists of items are provided by way of illustration and shall not be used to limit the scope of this disclosure.

A service, function, or resource is not limited to a single service, function, or resource; usage of these terms may refer to a grouping of related services, functions, or resources, which may be distributed or aggregated. The use of memory, database, information base, data store, tables, hardware, cache, and the like may be used herein to refer to system component or components into which information may be entered or otherwise recorded. The terms “data,” “information,” along with similar terms, may be replaced by other terminologies referring to a group of one or more bits, and may be used interchangeably. The terms “packet” or “frame” shall be understood to mean a group of one or more bits. The term “frame” shall not be interpreted as limiting embodiments of the present invention to Layer 2 networks; and, the term “packet” shall not be interpreted as limiting embodiments of the present invention to Layer 3 networks. The terms “packet,” “frame,” “data,” or “data traffic” may be replaced by other terminologies referring to a group of bits, such as “datagram” or “cell.” The words “optimal,” “optimize,” “optimization,” and the like refer to an improvement of an outcome or a process and do not require that the specified outcome or process has achieved an “optimal” or peak state.

It shall be noted that: (1) certain steps may optionally be performed; (2) steps may not be limited to the specific order set forth herein; (3) certain steps may be performed in different orders; and (4) certain steps may be done concurrently.

Any headings used herein are for organizational purposes only and shall not be used to limit the scope of the description or the claims. Each reference/document mentioned in this patent document is incorporated by reference herein in its entirety.

It shall also be noted that although embodiments described herein may be within the context of memory modules, aspects of the present disclosure are not so limited. Accordingly, the aspects of the present disclosure may be applied or adapted for use in other contexts.

### A. General Overview

As noted above, the physical design of certain boards of an information handling system often includes a number of parallel sockets that are designed to receive modules, such as memory modules like dual inline memory modules (DIMMs). However, the increase in memory sockets on a board that has limited space has led to narrower spacing between sockets. This design increases the risk of a module accidentally being inserted into the empty space between adjacent sockets, rather than being directly inserted into a socket's slot/receptable. When a module is misaligned and pressed into the space between sockets, it can damage the components on the module, on the board, or both.

To address this misalignment issue, fillers or blocks may be placed into the space between sockets. These blocking feature, which are designed to fill the gaps between adjacent sockets, can be successful at preventing misalignment of a module during insertion. However, such designs have at least one significant a drawback—the blocking feature prevents more than just the misaligned module. Specifically, the blocking feature may obstruct cooling airflow directed to the module, which could result in potential thermal issues. Note that as the density of components on a board increase, so do the thermal issues. Thus, cooling airflow becomes increasingly critical. By blocking airflow, the densely packed modules can quickly overheat.

Accordingly, presented herein are embodiments comprise one or more mechanical stoppers or flanges, which are moveable relative to insertion and removal of a module. In one or more embodiments, the stopper/flange may be combined with or operate in conjunction module latch to form a latch-and-stopper system, which may be added to a socket or part of a socket system/component. In one or more embodiments, when a latch, which is engaged by the module, moves from one position (e.g., open) to another (e.g., closed), the stopper(s) extends and retracts accordingly.

### B. System Embodiments

As noted above, the physical design of certain boards of an information handling system often includes closely spaced connectors/sockets. The close proximity of the sockets can present challenges for correctly aligning and inserting a module into the receptable of the socket—especially if the spacing between sockets is physically close and is approximately the same size as the receptable.

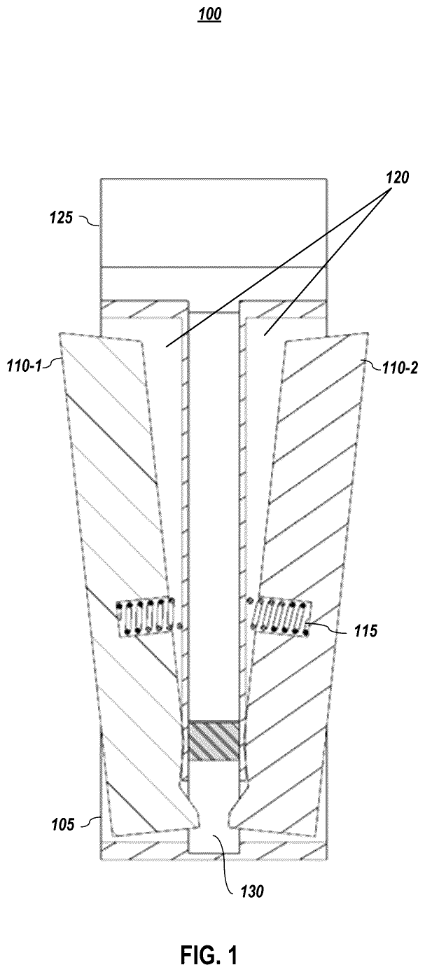

FIG. 1 depicts a cross-section view of part of a socket system with a gating/stopper/flange mechanism, according to embodiments of the present disclosure. In one or more embodiments, an apparatus for preventing mis-insertion of a module may comprise a pair of stoppers 110-1 and 110-2. The stoppers 110 may be attached to a socket housing 105 of a socket that is intended to receive a module (which shall be understood to include standalone component or a connector. In one or more embodiments, each stopper may be configured, when attached to the socket housing 105 of the socket:
(1) to be in an outward position, when no module is in the socket—thereby forming a barrier between the socket and an adjacent socket to prevent incorrect insertion of a module into a space formed between the socket and the adjacent socket; and
(2) to move toward the socket housing by actuation by a latch 125/130 that engages the pair of stoppers when a module is inserted into the socket.

In one or more embodiments, each stopper of the pair of stoppers may be configured to be in an outward position when no module is in the socket to form the barrier between the socket and an adjacent socket by one or more spring mechanisms 115. The spring mechanism may be a spring, a compliant mechanism, or weighted to rest in the outward position.

In one or more embodiments, the actuator of the latch 125 comprises a foot portion 130 of the latch to interact with each of the stoppers 110 of the pair of stoppers to cause them to rotate inline or substantially inline with the socket housing when the module is inserted into the socket. By rotating inline or substantially inline with the socket housing, the stoppers reduce their restrictive effect on airflow into the space formed between the socket and the adjacent socket. That is, in one or more embodiments, in the latch's open position, springs push the stoppers outward, creating a barrier between adjacent sockets to prevent incorrect insertion. When the latch is closed, the stoppers rotate along the base of the ejection lever and retract into the socket housing, allowing airflow to reduce potential thermal risks. In one or more embodiments, the latch 125 may further comprise a clasp that helps hold the module in place in the socket once fully inserted into the socket.

In one or more embodiments, the socket housing may comprise one or more cavities 120 to receive the pair of stoppers when a module is in the socket. In such embodiments, after the module is inserted into the socket, each of the stoppers of the pair of stoppers is fully contained within the one or more cavities of the socket housing so as to not inhibit airflow into the space between the socket and the adjacent socket.

In one or more embodiments, the socket system apparatus may have stoppers at or near a first end of the socket, at or near a second end of the socket, or both.

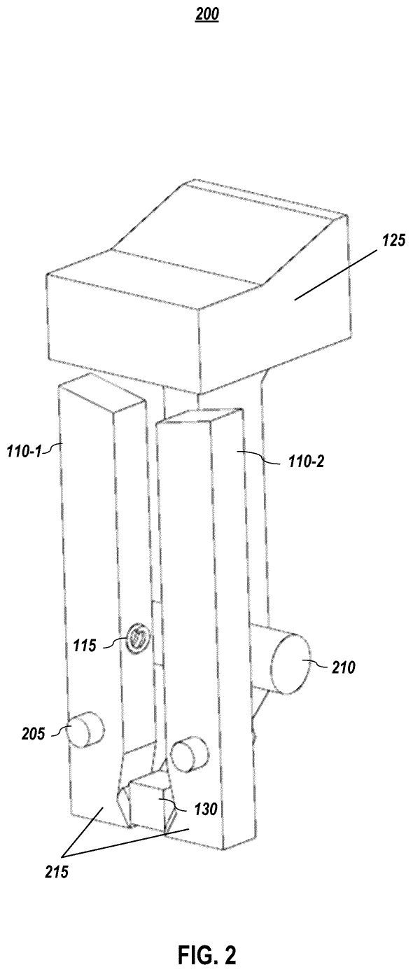

FIG. 2 depicts an isometric view of part of a socket system with a gating/stopper/flange mechanism, according to embodiments of the present disclosure. The depicted view shows the stoppers 110 in a retracted position. Also depicted in FIG. 2 are pivot points 205 about which the stoppers pivot. Also depicted is a pivot point 210 about which the latch 125 rotates as a module is inserted or removed from a socket slot. Finally, also depicted is a foot portion 130 of the latch 125 that engages with ends 215 of the stoppers to cause them to move inward when a module is inserted into a socket receptable.

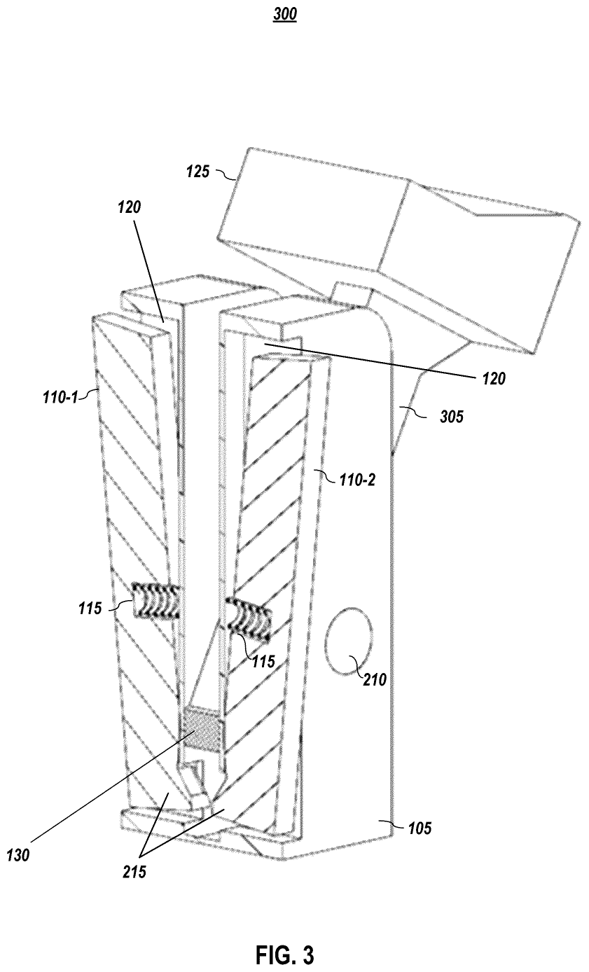

FIG. 3 depicts a partial cross-section view of part of a socket system with a gating/stopper/flange mechanism, according to embodiments of the present disclosure. The depicted embodiment shows the latch 125 that has a leg portion 305 that connects to the foot 130, which engages with the stoppers at the stoppers'ends 215.

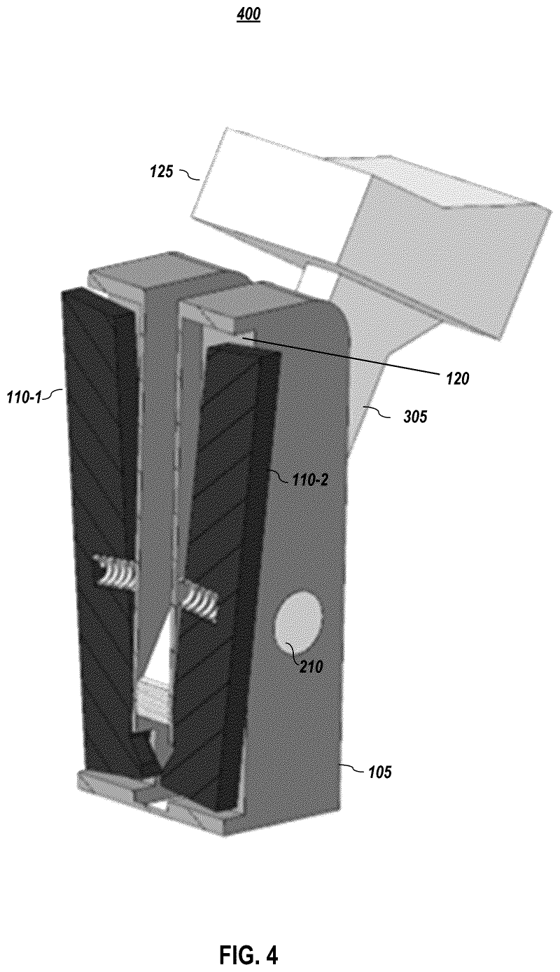

FIG. 3 shows the latch's pivot point 210 in place in a socket housing, which includes cavities 120 that receive the stoppers 110 when retracting. FIG. 4 depicts a shaded partial cross-section view of the partial view of the socket system of FIG. 3.

By default, the springs 115 integrated in the housing 105 continually push the stoppers outward, creating a physical barrier. When the latch is in open position, its lower section separates from the stopper bases, allowing the springs to push the stoppers outward. As the latch 125 moves to the closed position, its bottom 130 contacts the bases 215 of the stoppers, causing the stoppers to rotate along their rotational center and retract into the cavities 120 of the housing 105.

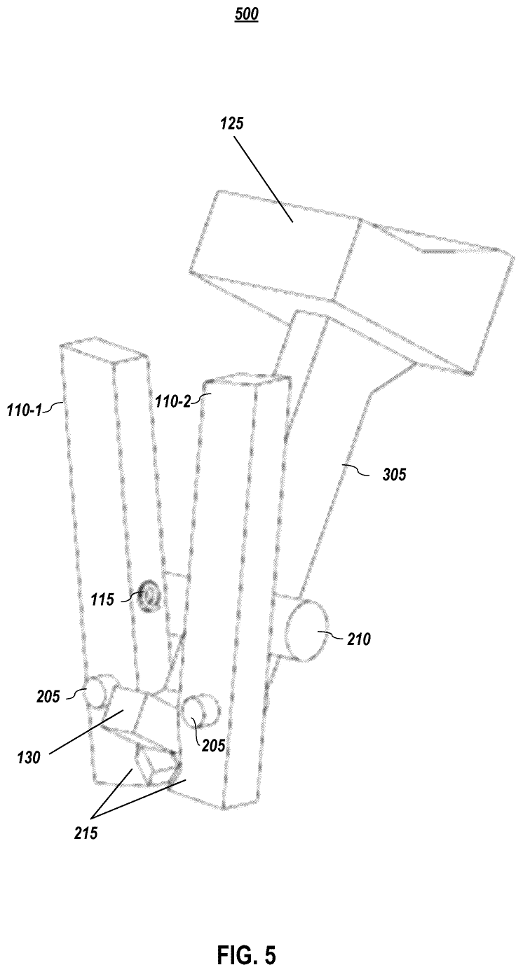

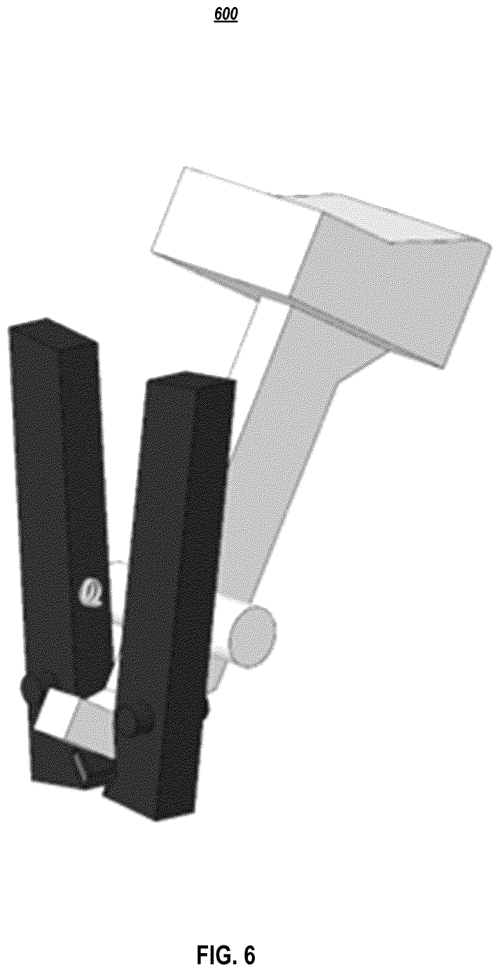

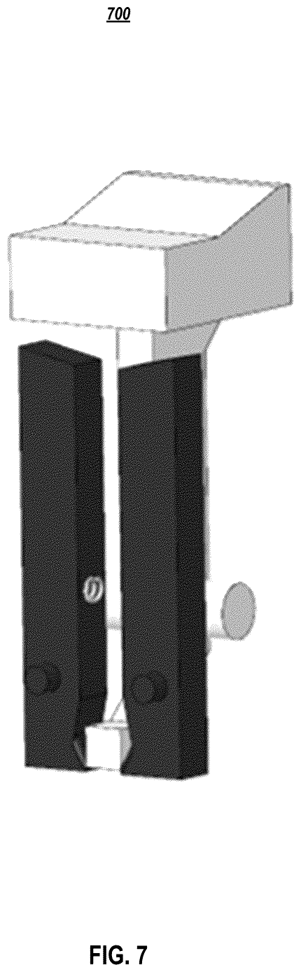

FIG. 5 depicts an isometric view of part of a socket system with a gating/stopper/flange mechanism in an extended or partially extended position, according to embodiments of the present disclosure. FIG. 6 depicts a shaded isometric view of the partial socket system of FIG. 5. FIG. 7 depicts a shaded isometric view of the partial socket system with the stoppers in a retracted position.

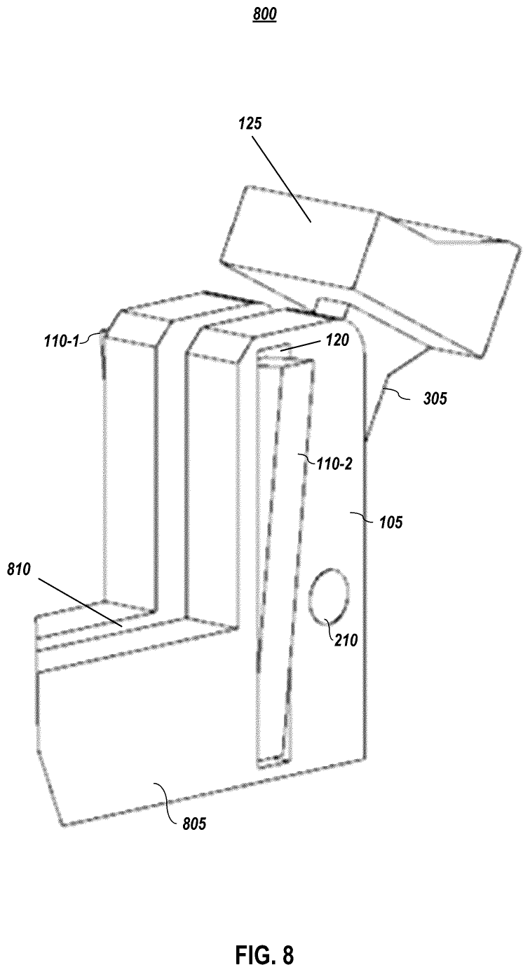

FIGS. 5-7 do not include a housing portion. FIG. 8 depicts an isometric view of part of a socket system with a gating/stopper/flange mechanism in mid-closed or mid-retracted position with a housing, according to embodiments of the present disclosure. In the depicted

FIG. 8 depicts an apparatus for preventing mis-insertion of a module comprises a first gate mechanism positioned at the first end of a socket, featuring a first flange (e.g., flange 110-1) that extends to form a barrier when no module is present and retracts via an actuator (e.g., latch mechanism 125) upon module insertion. This mechanism reduces airflow restriction between adjacent sockets. The gate mechanism may include a cavity 120 to in a housing 105 that receives the first flange when retracted, ensuring unobstructed airflow from the flange. Additionally, the first gate mechanism may include a second flange (e.g., flange 110-2) that extends to prevent incorrect insertion between the socket and a second adjacent socket (not shown), retracting similarly upon module insertion and being housed in a cavity. The cavities for the first and second flanges may be the same or different cavities.

In one or more embodiments, the apparatus may be integrated with the socket 805 that includes a receptable or slot 810 to receive the module. The apparatus may also include gate mechanisms at both ends of the socket 805 to ensure comprehensive protection against mis-insertion.

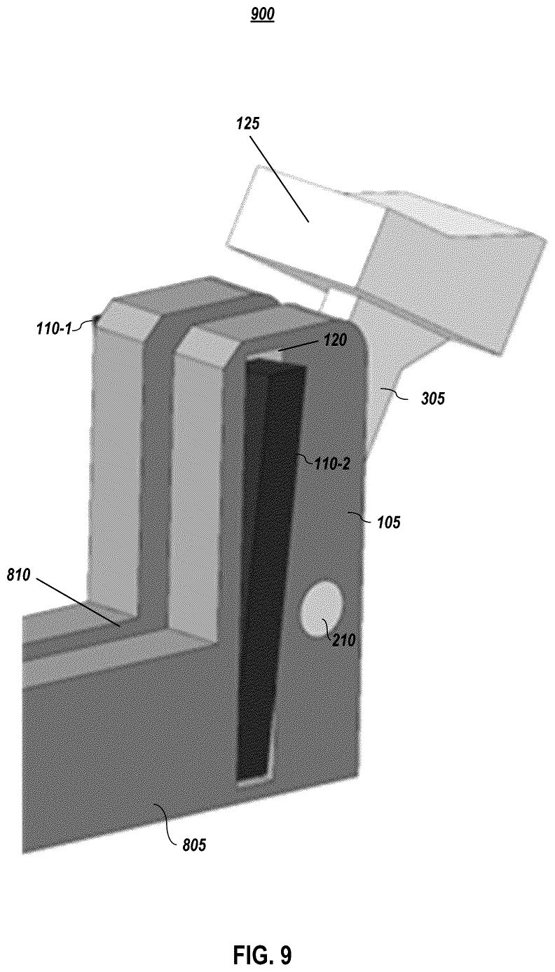

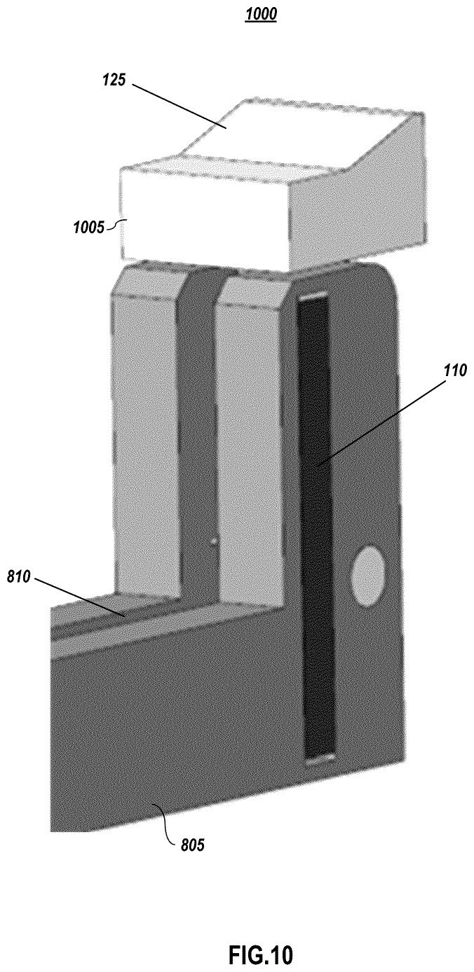

FIG. 9 depicts a shaded isometric view of FIG. 8, according to embodiments of the present disclosure. FIG. 10 depicts a shaded isometric view with the flange mechanism in a closed or retracted position, according to embodiments of the present disclosure.

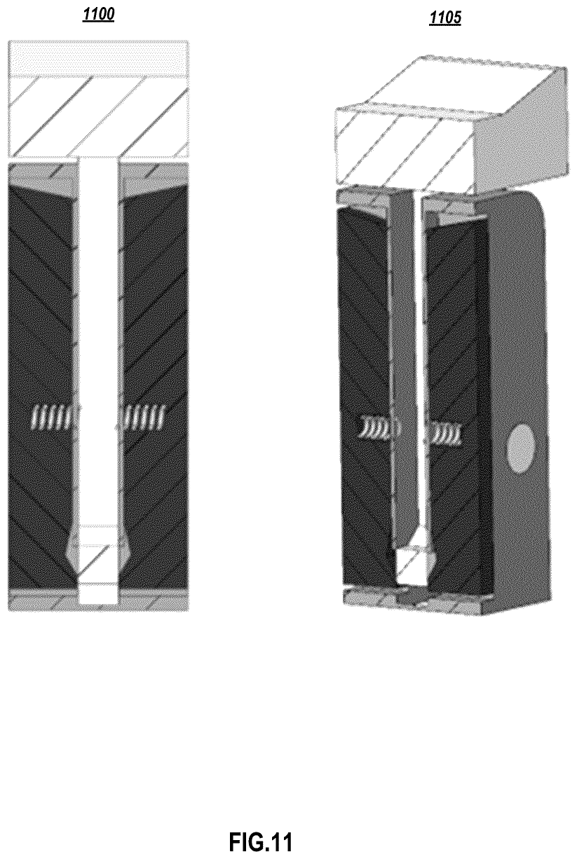

FIG. 11 depicts two partial cross-sectional shaded views of part of a socket system with a gating/stopper/flange mechanism in a closed or retracted position, according to embodiments of the present disclosure. The first view 1100 is a front view, and the second view 1105 is an isometric view.

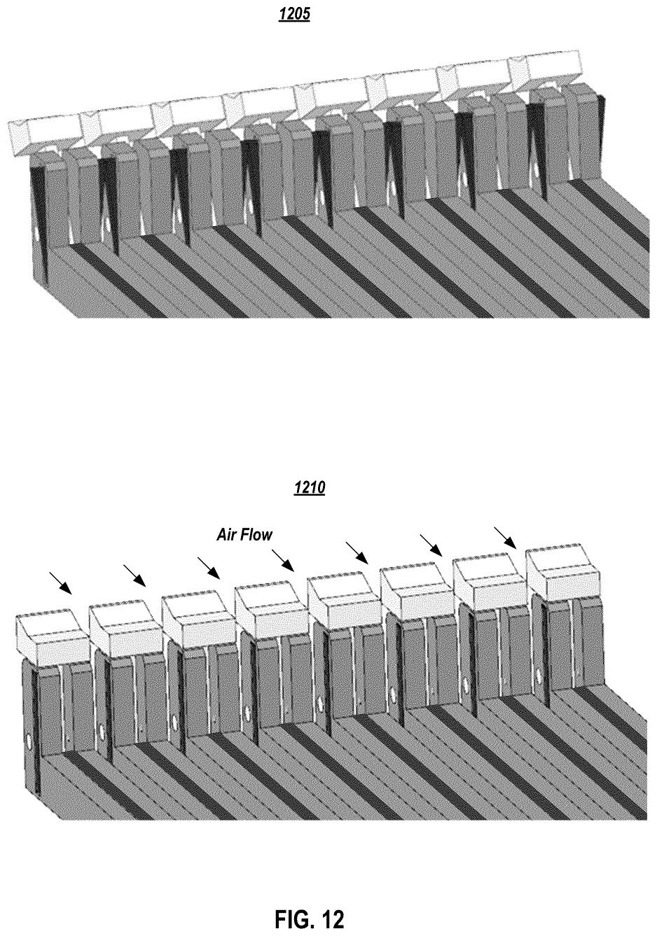

FIG. 12 depicts two partial shaded isometric views of part of a socket system with a gating/stopper/flange mechanism in a deployed/open/extended position 1205 and in a closed/retracted position 1210, according to embodiments of the present disclosure. When deployed, the stoppers extend outward, forming a barrier between adjacent sockets to prevent misalignment during insertion. In the retracted state, the stoppers may be retraced into a housing, allowing for airflow between the sockets.

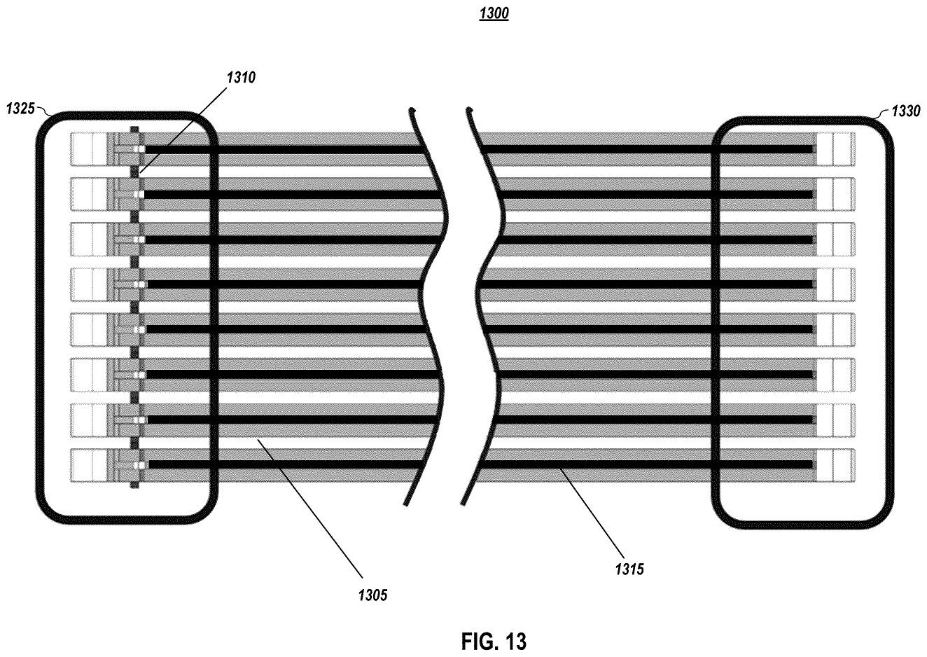

FIG. 13 depicts a top-down view of a set of socket systems with gating/stopper/flange mechanisms, according to embodiments of the present disclosure. FIG. 13 shows stopper apparatuses at both ends of the socket. The systems at the left side (within box 1325) have the stoppers 1310 in an extended position to help prevent misaligned insertion of a module into a space between socket systems (e.g., space 1305) when the module should be inserted into a socket slot (e.g., receptable 1315). In one or more embodiments, stopper apparatuses may be additionally or alternatively positioned at the other end of the socket (e.g., box 1320). If stoppers existed at the second end (e.g., box 1320), the stoppers in a retracted position would appear as shown in box 1320, retracted and not visible, so as to not inhibit airflow.

### C. Example Methodology Embodiments

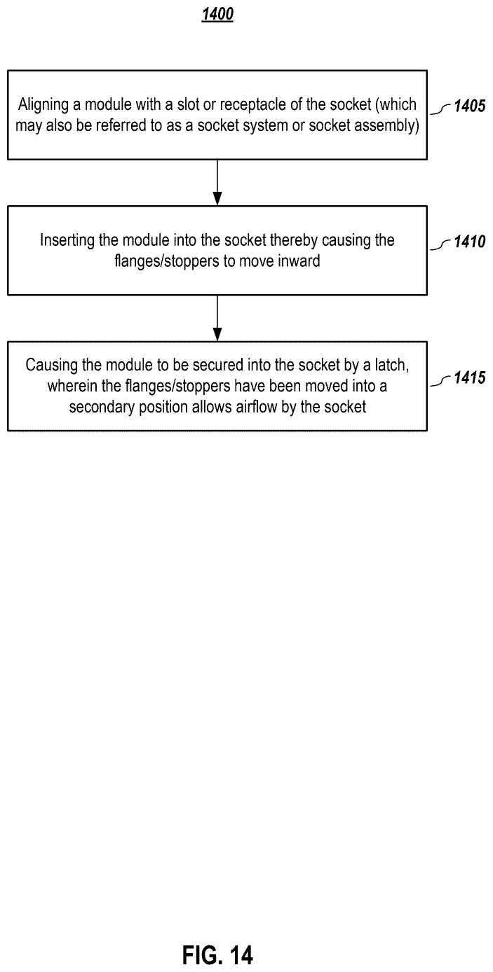

FIG. 14 depicts an example methodology for using a socket system, according to embodiments of the present disclosure. In one or more embodiments, a person or machine inserting a module (which may be a connector) aligns (1405) a module with a slot or receptacle of the socket, which may also be referred to as a socket system or socket assembly. The module is inserted (1410) into the socket thereby causing the flanges/stoppers to retract. In one or more embodiments, when the module is fully inserted, the module may be secured into the socket by a latch, wherein the flanges/stoppers have been moved into a secondary position allows airflow by the socket.

To remove the module, the latch may be moved back and the module removed. As the module is removed, the flanges move back into an extended position.

### D. Information Handling System Embodiments

In one or more embodiments, aspects of the present patent document may be directed to, may include, or may be implemented on one or more information handling systems (or computing systems). An information handling system/computing system may include any instrumentality or aggregate of instrumentalities operable to compute, calculate, determine, classify, process, transmit, receive, retrieve, originate, route, switch, store, display, communicate, manifest, detect, record, reproduce, handle, or utilize any form of information, intelligence, or data. For example, a computing system may be or may include a personal computer (e.g., laptop), tablet computer, mobile device (e.g., personal digital assistant (PDA), smart phone, phablet, tablet, etc.), smart watch, server (e.g., blade server or rack server), a network storage device, camera, or any other suitable device and may vary in size, shape, performance, functionality, and price. The computing system/information handling system may include random access memory (RAM), one or more processing resources such as a central processing unit (CPU) or hardware or software control logic, read only memory (ROM), and/or other types of memory. Additional components of the computing system may include one or more drives (e.g., hard disk drives, solid state drive, or both), one or more network ports for communicating with external devices as well as various input and output (I/O) devices. The computing system may also include one or more buses operable to transmit communications between the various hardware components.

An information handling system may comprise any of a number of sockets that may receive connectors or modules. Accordingly, one or more embodiments of the present patent document may be implemented in various applications with an information handling system.

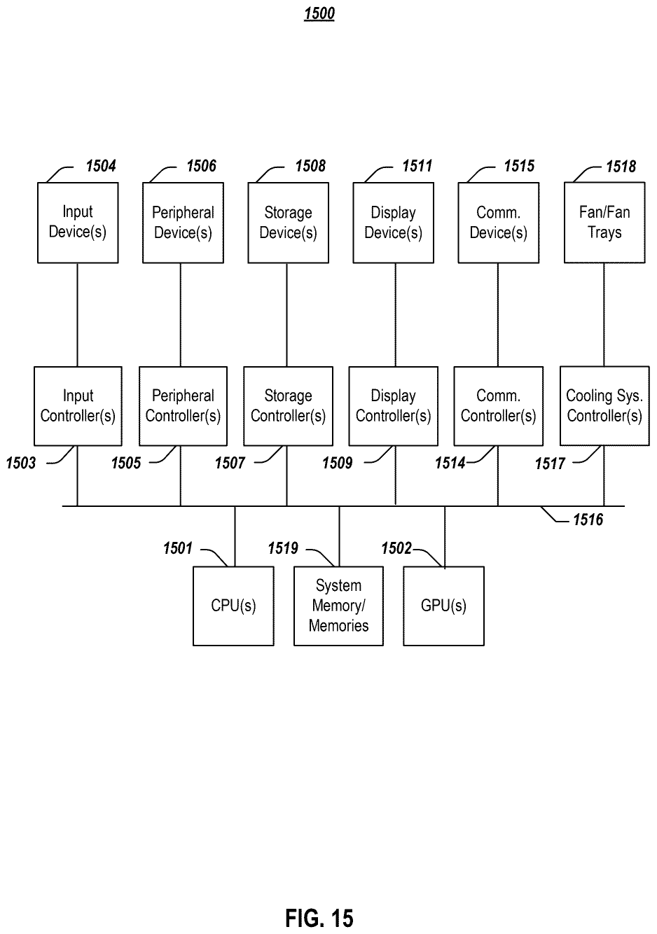

FIG. 15 depicts a simplified block diagram of an information handling system (or computing system), according to embodiments of the present disclosure. It will be understood that the functionalities shown for system 1500 may operate to support various embodiments of a computing system—although it shall be understood that a computing system may be differently configured and include different components, including having fewer or more components as depicted in FIG. 15.

As illustrated in FIG. 15, the computing system 1500 includes one or more CPUs 1501 that provides computing resources and controls the computer. CPU 1501 may be implemented with a microprocessor or the like and may also include one or more graphics processing units (GPU) 1502 and/or a floating-point coprocessor for mathematical computations. In one or more embodiments, one or more GPUs 1502 may be incorporated within the display controller 1509, such as part of a graphics card or a subcomponent. In one or more embodiments, the system may alternatively or additionally include one or more data processing units (DPUs) (not shown). In the realm of data centers and cloud computing, a DPU refers to a specialized processing unit designed to accelerate data processing tasks. DPUs are typically optimized for handling data-centric workloads such as networking, storage, security, and other tasks related to data processing and manipulation. DPUs often offload specific tasks from a main CPU, allowing for improved performance, efficiency, and scalability in data-intensive applications. They may include specialized hardware components and dedicated software to efficiently process and manage data flows within a system. The system 1500 may also include a system memory 1519, which may comprise RAM, ROM, or both.

A number of controllers and peripheral devices may also be provided, as shown in FIG. 15. An input controller 1503 represents an interface to various input device(s) 1504, such as a keyboard, mouse, touchscreen, stylus, microphone, camera, trackpad, display, etc. The computing system 1500 may also include a storage controller 1507 for interfacing with one or more storage devices 1508 each of which includes a storage medium such as magnetic tape or disk, or an optical medium that might be used to record programs of instructions for operating systems, utilities, and applications, which may include embodiments of programs that implement various aspects of the present disclosure. Storage device(s) 1508 may also be used to store processed data or data to be processed in accordance with the disclosure. The system 1500 may also include a display controller 1509 for providing an interface to a display device 1511, which may be a cathode ray tube (CRT) display, a thin film transistor (TFT) display, organic light-emitting diode, electroluminescent panel, plasma panel, or any other type of display. The computing system 1500 may also include one or more peripheral controllers or interfaces 1505 for one or more peripherals 1506. Examples of peripherals may include one or more printers, scanners, input devices, output devices, sensors, and the like. A communications controller 1514 may interface with one or more communication devices 1515, which enables the system 1500 to connect to remote devices through any of a variety of networks including the Internet, a cloud resource (e.g., an Ethernet cloud, a Fibre Channel over Ethernet (FCoE)/Data Center Bridging (DCB) cloud, etc.), a local area network (LAN), a wide area network (WAN), a storage area network (SAN) or through any suitable electromagnetic carrier signals including infrared signals. As shown in the depicted embodiment, the computing system 1500 comprises one or more fans or fan trays 1518 and a cooling subsystem controller or controllers 1517 that monitors thermal temperature(s) of the system 1500 (or components thereof) and operates the fans/fan trays 1518 to help regulate the temperature.

In the illustrated system, all major system components may connect to a bus 1516, which may represent more than one physical bus. In one or more embodiments, one or more connectors (i.e., sockets) may be used for connecting components. It should be noted that various system components may or may not be in physical proximity to one another. For example, input data and/or output data may be remotely transmitted from one physical location to another. In addition, programs that implement various aspects of the disclosure may be accessed from a remote location (e.g., a server) over a network. Such data and/or programs may be conveyed through any of a variety of machine-readable media including, for example: magnetic media such as hard disks, floppy disks, and magnetic tape; optical media such as compact discs (CDs) and holographic devices; magneto-optical media; and hardware devices that are specially configured to store or to store and execute program code, such as application specific integrated circuits (ASICs), programmable logic devices (PLDs), flash memory devices, other non-volatile memory (NVM) devices (such as 3D XPoint-based devices), and ROM and RAM devices.

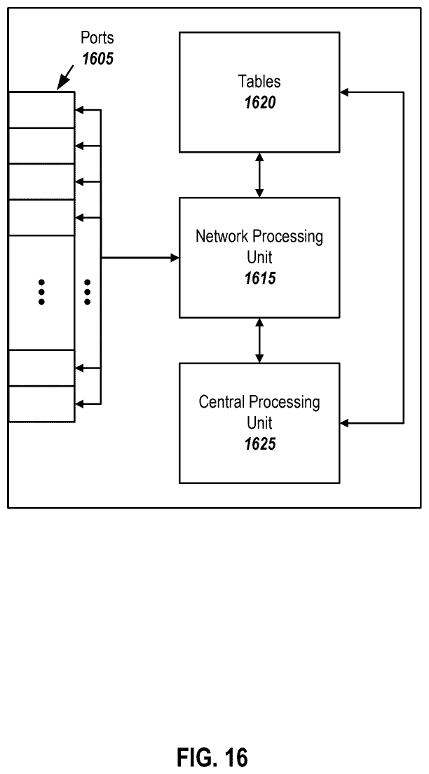

FIG. 16 depicts an alternative block diagram of an information handling system, according to embodiments of the present disclosure. It will be understood that the system 1600 may operate via support of one or more embodiments of the present disclosure—although it shall be understood that such system may be differently configured and include different components, additional components, or fewer components.

The information handling system 1600 may include a plurality of I/O ports 1605, a network processing unit (NPU) 1615, one or more tables 1620, and a CPU 1625. The system includes a power supply (not shown) and may also include other components, which are not shown for sake of simplicity.

In one or more embodiments, the I/O ports 1605 may be connected via one or more cables to one or more other network devices or clients. The network processing unit 1615 may use information included in the network data received at the node 1600, as well as information stored in the tables 1620, to identify a next device for the network data, among other possible activities. In one or more embodiments, a switching fabric may then schedule the network data for propagation through the node to an egress port for transmission to the next destination.

It shall be noted that alternative implementations are possible, including different hardware implementations. Accordingly, the “means” terms in any claims are intended to cover different hardware implementations. With these implementation alternatives in mind, it is to be understood that the figures and accompanying description provide physical and functional information one skilled in the art would require to make and use different embodiments that support that same functional output.

It shall be noted that embodiments of information handling systems described above may comprise non-transitory, tangible computer-readable media include, for example: magnetic media such as hard disks, floppy disks, and magnetic tape; optical media such as compact discs (CDs) and holographic devices; magneto-optical media; and hardware devices that are specially configured to store or to store and execute program code, such as ASICs, PLDs, flash memory devices, other non-volatile memory devices (such as 3D XPoint-based devices), ROM, and RAM devices. Examples of computer code include machine code, such as produced by a compiler, and files containing higher level code that are executed by a computer using an interpreter. Embodiments of the present disclosure may be implemented in whole or in part as originally part of an information handling system or as an upgrade to an existing information handling system. In distributed computing environments, program modules may be physically located in settings that are local, remote, or both.

One skilled in the art will also recognize that a number of the elements described above may be physically and/or functionally separated into elements or combined together.

It will be appreciated by those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claim may be arranged differently including having multiple dependencies, configurations, and combinations.

What is claimed is:

1. An apparatus for preventing mis-insertion of a module, the apparatus comprising:
a pair of stoppers for attaching to a socket housing of a socket for receiving a module, wherein each stopper is configured, when attached to the socket housing of the socket:
to be in an outward position, when no module is in the socket, to form a barrier between the socket and an adjacent socket to prevent incorrect insertion of a module into a space formed between the socket and the adjacent socket; and
to move toward the socket housing by actuator of a latch that engages the pair of stoppers when a module is inserted into the socket.

2. The apparatus of claim 1 wherein:
the actuator of the latch comprises a foot portion of the latch to interact with each of the stoppers of the pair of stoppers to cause them to rotate inline or substantially inline with the socket housing when the module is inserted into the socket to reduce restriction of airflow into the space formed between the socket and the adjacent socket.

3. The apparatus of claim 1 wherein:
the socket housing comprises one or more cavities to receive the pair of stoppers when a module is in the socket.

4. The apparatus of claim 3 wherein:
after the module is inserted into the socket, each of the stoppers of the pair of stoppers is fully contained within the one or more cavities of the socket housing so as to not inhibit airflow into the space between the socket and the adjacent socket.

5. The apparatus of claim 1 wherein:
each stopper of the pair of stoppers is configured to be in the outward position, when no module is in the socket, to form the barrier between the socket and an adjacent socket by one or more spring mechanisms.

6. The apparatus of claim 1 wherein the socket comprises:
the pair of stoppers attached to the socket housing at or near a first end of the socket; and
a second pair of stoppers attached to a second socket housing at or near a second end of the socket.

7. The apparatus of claim 1 wherein:
the latch further comprises a clasp that helps hold the module in place in the socket once fully inserted into the socket.

8. An apparatus for preventing mis-insertion of a module comprising:
a first gate mechanism positioned at or near a first end of a socket that is configured to receive a module, the first gate mechanism comprising a first flange portion that is configured:
to be in an extended position, when no module is in the socket, to form a barrier between the socket and an adjacent socket to prevent incorrect insertion of a module into a space formed between the socket and the adjacent socket; and
to move into a retracted position by an actuator when a module is inserted into the socket.

9. The apparatus of claim 8 wherein:
the actuator interacts with the first gate mechanism to cause the first flange to move to the retracted position when the module is in the socket to reduce restriction of airflow into the space formed between the socket and the adjacent socket.

10. The apparatus of claim 8 wherein:
the first gate mechanism or the socket comprises a cavity to receive the first flange of the first gate mechanism when the module is in the socket.

11. The apparatus of claim 10 wherein:
after the module is inserted into the socket, the first flange of the first gate mechanism is contained within or substantially contained within the cavity so as to not inhibit airflow into the space between the socket and the adjacent socket.

12. The apparatus of claim 8 wherein:
the first gating mechanism comprises a second flange, in which the second flange of the first gate mechanism is configured:
to be in an extended position, when no module is in the socket, to form a barrier between the socket and a second adjacent socket that is on another side of the socket to prevent incorrect insertion of a module into a space formed between the socket and the second adjacent socket; and
to move into a retracted position when a module is inserted into the socket.

13. The apparatus of claim 12 wherein:
after the module is inserted into the socket, the second flange of the first gate mechanism is contained within or substantially contained within a cavity of the first gating mechanism or the socket so as to not inhibit airflow into the space between the socket and the second adjacent socket.

14. The apparatus of claim 13 wherein:
the cavity that receives the first flange is a different cavity than the cavity that receives the second flange; or
the cavity that receives the first flange is a same cavity as the cavity that receives the second flange.

15. The apparatus of claim 8 comprising:
the first gating mechanism positioned at or near a first end of the socket; and
a second gating mechanism positioned at or near a second end of the socket.

16. A method comprising:
inserting a module into a receptable of a socket that is configured to receive the module, the socket comprising:
a first gate mechanism positioned at or near a first end of the socket, the first gate mechanism comprising a first flange portion that is configured:
to be in an extended position, when no module is in the socket, to form a barrier between the socket and an adjacent socket to prevent incorrect insertion of the module into a space formed between the socket and the adjacent socket; and
to move into a retracted position by an actuator when a module is inserted into the socket.

17. The method of claim 16 wherein:
the actuator interacts with the first gate mechanism to cause the first flange to move to the retracted position when the module is in the socket to reduce restriction of airflow into the space formed between the socket and the adjacent socket.

18. The method of claim 16 wherein:
the socket comprises a cavity to receive the first flange of the first gate mechanism when the module is in the socket.

19. The method of claim 18 wherein:
after the module is inserted into the socket, the first flange of the first gate mechanism is contained within or substantially contained within the cavity so as to not inhibit airflow into the space between the socket and the adjacent socket.

20. The method of claim 16 wherein:
the first gating mechanism comprises a second flange, in which the second flange of the first gate mechanism is configured:
to be in an extended position, when no module is in the socket, to form a barrier between the socket and a second adjacent socket that is on another side of the socket to prevent incorrect insertion of a module into a space formed between the socket and the second adjacent socket; and
to move into a retracted position when a module is inserted into the socket.
